(19) United States
(12) Patent Application Publication
(10) Pub. No.: US 2017/0177513 A1
(43) Pub. Date: Jun. 22, 2017

(54) FIXED LATENCY MEMORY CONTROLLER, ELECTRONIC APPARATUS AND CONTROL METHOD

(71) Applicant: SAMSUNG ELECTRONICS CO., LTD., Suwon-si (KR)

(72) Inventors: Suk-jin KIM, Seoul (KR); Dong-kwan SUH, Yongin-si (KR)

(73) Assignee: SAMSUNG ELECTRONICS CO., LTD., Suwon-si (KR)

(21) Appl. No.: 15/177,589

(22) Filed: Jun. 9, 2016

(30) Foreign Application Priority Data
Dec. 16, 2015 (KR) 10-2015-0180044

(51) Int. Cl. G06F 13/16; G11C 7/10

(52) U.S. Cl. CPC G06F 13/161; G11C 7/1072

(57) ABSTRACT

A memory controller, electronic apparatus, and control method are provided. The memory controller includes a communication module configured to perform communication with a main memory and a processor configured to, based on a time duration of receiving a response corresponding to an request to access a main memory, determine the actual latency period of the request, compare the actual latency period with an estimated latency period, and perform a latency adjustment operation corresponding to a result of the comparison.

### CROSS-REFERENCE TO RELATED APPLICATION

This application claims priority from Korean Patent Application No. 10-2015-0180044, filed in the Korean Intellectual Property Office on Dec. 16, 2015, the disclosure of which is incorporated herein by reference in its entirety.

### BACKGROUND

1. Field

Methods and apparatuses consistent with the exemplary embodiments relate to a memory controller, an electronic apparatus, and a control method thereof. More particularly, aspects of the exemplary embodiments relate to a memory controller which adjusts latency of a main memory access request, an electronic apparatus, and a control method thereof.

2. Description of the Related Art

As electronic technology advances, so too does the ability to capture digital images in greater detail, requiring processors to process an ever increasing amount of image data, and utilize increasingly complex algorithms with which to process data. For example, a driver assistance system such as a system for traffic lane recognition, obstacle identification, passenger recognition, etc. in a smart car should quickly process a large amount of images in real time. Likewise, as Digital Television (DTV) and mobile devices have developed, along with corresponding applications for those devices, the amount of image data used for image processing has increased in these applications as well.

Accordingly, a kernel function for image processing, or effective processing of functions, has become an increasingly important factor in processing Ultra High Definition (UHD) level images of 4K or 8K. Conventionally electronic apparatus such as a DTV or a mobile device use a pipeline to effectively process tasks in hardware, including image data tasks. Large scale memory, or a buffer is required at each stage of the pipeline as the amount of data transferred between stages can be quite great.

FIG. 1 is a block diagram method of processing data using a conventional pipeline.

Referring to FIG. 1, a processor stores input/output data generated at each pipeline stage in a buffer which may be implemented as a memory. In the case of processing input/output data of a high-definition image such as a (UHD) level image, the size of the needed buffer becomes significant, and can take up more than ¾ of the entire hardware.

Accordingly, a method of reducing the size of the entire hardware, by reducing the size of the buffer needed at each pipeline stage, is required. Main memory may be used to store input/output data including UHD data rather than a buffer at each pipeline stage. However there is a long latency period as a result, and the problem of irregular latency also occurs. Accordingly, a method of effectively using main memory by fixing the latency period to a certain value and avoiding the irregular latency period is required.

### SUMMARY

Aspects of the exemplary embodiments relate to a memory controller, which adjusts the latency period of a main memory access request to a fixed latency period, an electronic apparatus and a control method of the memory controller.

According to an aspect of an exemplary embodiment, there is provided a memory controller including a communication module, configured to perform communication with a main memory and a processor configured to, based on a time duration of receiving a response corresponding to a request to access the main memory, determine the actual latency period of the request, compare the actual latency period with an estimated latency period, and perform a latency adjustment operation corresponding to a result of the comparison.

The processor, in response to the actual latency period of the request being less than the estimated latency period, may buffer the response corresponding to the access request based on the time difference between the actual latency period and the estimated latency period.

The processor, in response to the actual latency period of the request being greater than the estimated latency period, may stall the processor based on the time difference between the actual latency period and the estimated latency period.

The processor may assign a tag ID to the access request in order to identify the access request, and may determine the actual latency period of the request based on the tag ID and the time duration of receiving the response.

The processor may include a tag ID generator configured to assign a tag ID for identifying the access request, and a latency handler configured to perform latency adjustment operations.

The access request regarding the main memory may be a request to access one-off data stored in the memory.

The main memory may be a dynamic random access memory (DRAM).

According to an aspect of an exemplary embodiment, there is provided an electronic apparatus including a main memory and a memory controller configured to transmit an access request to the main memory, determine the actual latency period of the request based on the time duration of receiving a response corresponding to the access request, compare the actual latency period with an estimated latency period, and perform a latency adjustment operation according to a result of the comparison.

According to an exemplary embodiment, there is provided a control method of a memory controller including receiving a response corresponding to request to access a main memory, determining the actual latency period of the request based on the time duration of receiving the response, comparing the actual latency period with an estimated latency period, and performing a latency adjustment operation according to a result of the comparison.

The latency adjustment operation may include, in response to the actual latency period of the request being less than the estimated latency period, buffering the response corresponding to the request based on the time difference between the actual latency period and the estimated latency period.

The latency adjustment operation may include, in response to the actual latency period of the request being greater than the estimated latency period, stalling a processor based on the time difference between the actual latency period and the estimated latency period.

Determining the actual latency period may include assigning a tag ID for identifying the access request to the access request, and determining the actual latency period of the request based on the tag ID and the time duration of receiving the response.

The access request regarding main memory may be a request to access one-off data stored in the main memory.

The main memory may be a dynamic random access memory (DRAM).

According to the above-described aspects of the exemplary embodiments, main memory can be effectively used by adjusting the latency period of a main memory access request to a fixed latency period.

### BRIEF DESCRIPTION OF THE DRAWINGS

The above and/or other aspects will be more apparent by describing certain exemplary embodiments with reference to the accompanying drawings, in which:

FIG. 1 is a block diagram method of processing data using a conventional pipeline;

FIG. 2 is a block diagram illustrating a configuration of an electronic apparatus according to an exemplary embodiment;

FIG. 3 is a block diagram illustrating a configuration of a memory controller according to an exemplary embodiment;

FIG. 4 is a block diagram illustrating a detailed configuration of a memory controller according to an exemplary embodiment;

FIG. 5 is a view illustrating a detailed area ratio of a buffer according to an exemplary embodiment; and

FIGS. 6 and 7 are flowcharts illustrating a control method of a memory controller according to an exemplary embodiment.

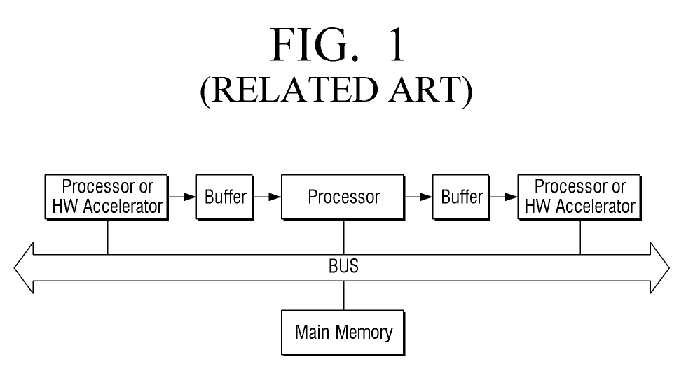

### DETAILED DESCRIPTION OF EXEMPLARY EMBODIMENTS

Hereinafter, various exemplary embodiments will be explained in detail with reference to the accompanying drawings. The embodiments to be described hereinafter may be variously modified. Specific embodiments may be illustrated in the drawings and may be described in detail in the detailed description. However, the specific embodiments disclosed in the accompanying drawings are merely for easy understanding of the various embodiments of the present disclosure. Accordingly, the technical idea of the present disclosure is not limited to the specific embodiments disclosed in the accompanying drawings, but it should be understood that the present disclosure includes all equivalents and substitutions that are included in the idea and the technical range of the present disclosure. However, in describing the present disclosure, well-known element structures and technologies are not described in detail since they would obscure the disclosure in unnecessary detail.

Although the terms including ordinal numbers “first,” “second,” and so forth are used to describe diverse elements, such elements are not limited by the terms. The terms are used only to discriminate one element from other elements.

The term “includes” or “has” used in the description represents that the features, figures, steps, operations, constituent elements, components, or combinations thereof exist, and thus the term should be understood that existence or addition of one or more other features, figures, steps, operations, constituent elements, components, or combinations thereof are not pre-excluded. The term “connected to” or “coupled to” that is used to designate a connection or coupling of one element to another element includes both a case that an element is “directly connected or coupled to” another element and a case that an element is connected or coupled to another element via still another element. In this case, the term “directly connected to” or “directly coupled to” means that an element is connected or coupled to another element without intervention of any other element.

In embodiments of the present disclosure, the term “module” or “portion,” as used herein, means, but is not limited to, software or hardware component or a combination thereof, which performs certain tasks. Further, “a plurality of modules or portions” may be integrally formed as at least one module and may be implemented by at least one processor except for “modules” or “portions” that are required to be implemented by specific hardware.

A singular form may include a plural form as long as not specifically mentioned in a sentence.

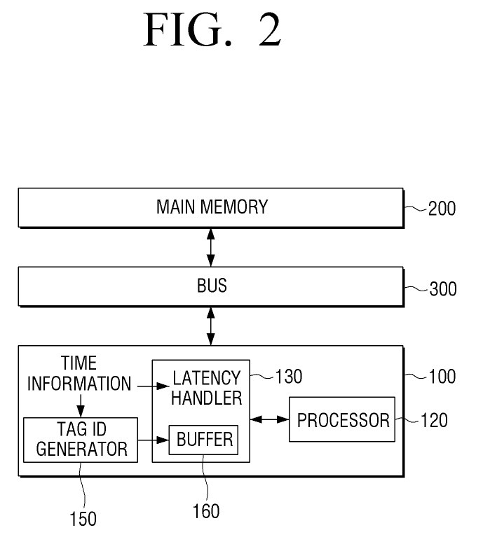

FIG. 2 is a block diagram illustrating a configuration of an electronic apparatus according to an exemplary embodiment.

As illustrated in FIG. 2, an electronic apparatus 20 according to an exemplary embodiment includes a memory controller 100, a main memory 200 and a bus 300.

Memory controller 100 may be configured in the form of a processor, contained within a processor, contain a processor, or may be configured as a separate apparatus.

Specifically, memory controller 100 communicates with main memory 200, via bus 300, and determines the actual latency period of a request to access main memory 200 based on the response time, or time duration, of receiving the access request. Here, the actual latency period refers to the time that it takes to transmit an action request and receive a response regarding the access request. The access request regarding main memory 200 may be a request to access one-off data stored in main memory 200, and main memory 200 may be a dynamic random access memory (DRAM). However, this is only an example, and the access request regarding main memory 200 may be various types of access requests, and main memory 200 may be various types of memories other than a DRAM.

Memory controller 100 may determine the actual latency period of an access request regarding main memory 200, compare the actual latency period with an estimated latency period, and perform a latency adjustment operation corresponding to a result of the comparison. Here, the latency adjustment operation corresponding to the comparison result may be to buffer the response or stall a processor. Specifically, if the actual latency period of the access request regarding main memory 200 is less than the estimated latency period, memory controller 100 may buffer a response corresponding to the access request regarding main memory 200 based on a time difference between the actual latency period and the estimated latency period.

In other words, if the response corresponding to the access request regarding main memory 200 is received faster than the estimated latency period, memory controller 100 may buffer the response corresponding to the access request based on the difference between the actual latency period and the estimated latency period to implement behavior that is the same as when the response is received after the estimated latency period. For example, if the response corresponding to the request to access main memory 200 is received one second faster than an estimated latency period, memory controller 100 may perform a latency adjustment operation and store the response corresponding to the access request in buffer 160, then continue memory controllers 100 handling of the response after one second has elapsed. Buffer 160 stores data such as the response to an access request transmitted from outside temporarily. Specifically, buffer 160 may store a response corresponding to an access request regarding main memory 200 for a predetermined time so as for processor 120 to perform a latency adjustment operation corresponding to the response after the predetermined time elapses. Buffer 160 is generally implemented as a memory, but is not limited thereto.

On the other hand, if the actual latency period of the request to access main memory 200 is greater than the estimated latency period, memory controller 100 may stall processor 120 based on a time difference between the actual latency period and the estimated latency period. If processor 120 is stalled for a predetermined time, processor 120 does not operate for the predetermined time and thus the actual latency period of the access request regarding main memory 200 is substantially reduced.

For example, if the response corresponding to the request to access main memory 200 is received one second later than the estimated latency period, memory controller 100 may adjust the actual latency period of the access request by stalling processor 120 for one second.

In addition, memory controller 100 may assign a tag ID for identifying an access request to the access request. Specifically, when an access request to access main memory 200 is transmitted from processor 120, memory controller 100 may assign a tag ID to each access request to identify the access request.

Memory controller 100 may determine the actual latency period of an access request based on the tag ID assigned to the access request regarding main memory 200 and the time duration of receiving a response corresponding to the access request regarding main memory 200. Specifically, memory controller 100 may identify an access request based on the tag ID assigned to the access request, and determine the difference in time between the time of receiving a response corresponding to the identified access request and the time of transmitting the identified access request as the actual latency period of the access request. However, this is only an example, and when determining the actual latency period of the access request, information regarding time other than the transmission time of the access request and reception time of the response corresponding to the access request may be considered.

In addition, memory controller 100 may include tag ID generator 150 to assign a tag ID for identifying an access request and latency handler 130 to control latency adjustment operations of an access request. Here, tag ID generator 150 may generate and assign a tag ID to each access request to identify the access request regarding main memory 200, transmitted from processor 120, and latency handler 130. If the actual latency period of an access request is less than an estimated latency period, latency handler 130 may buffer the access request based on the time difference between the actual latency period and the estimated latency period. If the actual latency period of the access request is greater than the estimated latency period, latency handler 130 may stall processor 120 based on the time difference between the actual latency period and the estimated latency period.

Main memory 200 may store input/output data generated by processor 120 or store one-off data to perform an algorithm performed in processor 120. In addition, when an access request is received, main memory 200 may transmit a response corresponding to the access request. Main memory 200 may be implemented as a DRAM, but is not limited thereto and may be implemented as other types of memories.

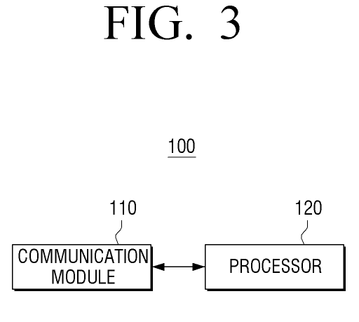

FIG. 3 is a block diagram illustrating configuration of a memory controller according to an exemplary embodiment.

As illustrated in FIG. 3, memory controller 100 includes a communication module 110 and a processor 120. Communication module 110 communicates with main memory 200 via bus 300. Specifically, if a predetermined event occurs, such as an access request regarding main memory, communication module 110 may communicate with main memory 200 according to a pre-defined communication method. If an access request regarding main memory 200 is generated in processor 120, communication module 110 may transmit the generated access request to main memory 200, and receive a response corresponding to the access request from main memory 200.

When the response corresponding to the access request regarding main memory 200 is received through communication module 110, processor 120 may determine the actual latency period of the access request based on the time duration of receiving the response.

In addition, processor 120 may determine the actual latency period of the access request regarding main memory 200, compare the actual latency period with estimated latency period, and perform a latency adjustment operation corresponding to a result of the comparison. Specifically, if the actual latency period of the request to access main memory 200 is less than the estimated latency period, processor 120 may buffer the response requesting access to main memory 200 based on the time difference between the actual latency period and the estimated latency period.

If the estimated latency period of a first access request is three seconds and a response corresponding to the first access request, which is received through communication module 110 in two seconds, processor 120 may perform a latency adjustment operation and store the response corresponding to the first access request in buffer 160 and then, continue handling the response to the access request after one second elapses. Accordingly, processor 120 may perform the latency adjustment operation in the same way as when the latency of the first access request is three seconds.

In addition, if the actual latency period of the access request regarding main memory 200 is greater than the estimated latency period, memory controller 100 may stall processor 120 based on the time difference between the actual latency period and the estimated latency period. When processor 120 is stalled the predetermined time, processor 120 does not operate for the predetermined time and thus, the actual latency period of the access request regarding main memory 200 substantially reduced.

In other words, if processor 120 is stalled for the predetermined time, there is the effect that the time does not elapse during the stalled predetermined time in processor 120 and thus, the actual latency period may be substantially reduced.

For example, if the estimated latency period of a second access request is two seconds and a response corresponding to the second access request, is received through communication module 110 in four seconds, a latency adjustment operation according to the second access request may be performed. Processor 120 may be stalled for two seconds. The effect is that time does not elapse in processor 120 for the stalled two seconds, and thus the operation may be performed in the same way as when the actual latency period of the second access request is two seconds.

In addition, processor 120 may assign a tag ID for identifying an access request to the access request. Specifically, if a request to access main memory 200 is transmitted, processor 120 may assign a tag ID to each access request to identify the access request.

Processor 120 may determine the actual latency period of an access request based on a tag ID assigned to the access request regarding main memory 200 and the time duration of receiving a response corresponding to the access request regarding main memory 200. Specifically, processor 120 may identify an access request based on a tag ID assigned to the access request and determine the difference in time between the time of receiving a response corresponding to the identified access request and the time of transmitting the identified access request as the actual latency period of the access request.

In addition, processor 120 may include tag ID generator 150 to assign a tag ID for identifying an access request and latency handler 130 to control latency adjustment operations of an access request. Here, tag ID generator 150 may generate and assign tag ID to each access request in order to identify the access request regarding a main memory, transmitted from processor 120, and latency handler 130, if the latency of an access request is less than an estimated latency period, latency handler 130 may buffer the response to the access request based on the time difference between the actual latency period, and the estimated latency period. If the actual latency period of the access request is greater than an estimated latency period, latency handler 130 may stall processor 120 based on the time difference between the actual latency period and the estimated latency period.

According to the above-described various exemplary embodiments, main memory 200 can be effectively used by adjusting the latency of main memory access request to a fixed latency period.

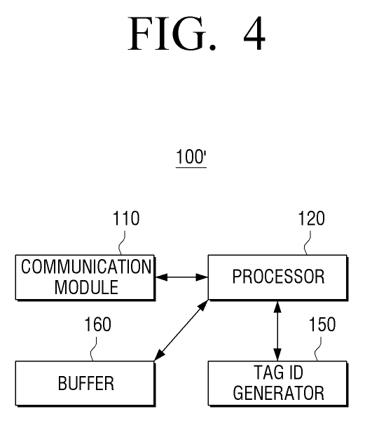

FIG. 4 is a block diagram illustrating a detailed configuration of a memory controller according to an exemplary embodiment.

Referring to FIG. 4, a memory controller 100′ includes communication module 110, processor 120, buffer 160, tag ID generator 150, and latency handler 130.

Communication module 110 performs communication with main memory 200. Here, communication module 110 may perform communication with the main memory 200 through various communication methods such as BlueTooth (BT), Wireless Fidelity (Wi-Fi), Zigbee, Infrared (IR), Serial Interface, Universal Serial Bus (UBS), Near Field Communication (NFC), etc.

When the response corresponding to the request to access main memory 200 is received through communication module 110, processor 120 may determine the actual latency period of the access request based on the time duration of receiving the response.

In addition, processor 120 may determine the actual latency period of the request to access main memory 200, compare the determined actual latency period with an estimated latency period, and perform a latency adjustment operation corresponding to a result of the comparison. Specifically, if the actual latency period of the access request regarding main memory 200 is less than the estimated latency period, processor 120 may buffer the response corresponding to the request to access main memory 200 based on the time difference between the actual latency period and the estimated latency period.

On the other hand, if the actual latency period of the access request regarding main memory 200 is greater than an estimated latency period, memory controller 100 may stall processor 120 for a predetermined time. When processor 120 is stalled for the predetermined time, processor 120 does not operate for the predetermined time and thus, the actual latency period of the access request regarding main memory 200 is substantially reduced.

In addition, processor 120 may assign a tag ID for identifying an access request to the access request. Specifically, if a request to access main memory 200 is transmitted, processor 120 may assign a tag ID to each access request to identify the access request.

Processor 120 may determine the actual latency period of an access request based on a tag ID assigned to the access request regarding main memory 200 and the time duration of receiving a response corresponding to the access request regarding main memory 200. Specifically, processor 120 may identify an access request based on a tag ID assigned to the access request and determine the difference between the time of receiving a response corresponding to the identified access request and the time of transmitting the identified access request as the actual latency period of the access request.

In addition, processor 120 may include a tag ID generator 150 to assign a tag ID for identifying an access request and latency handler 130 to control latency adjustment operations of an access request. Here, tag ID generator 150 may generate and assign tag ID to each access request in order to identify the access request regarding main memory 200, transmitted from processor 120, and latency handler 130. If the actual latency period of an access request is less than an estimated latency period, latency handler 130 may buffer the response to the access request based on the time difference between the actual latency period and the estimated latency period. If the actual latency period of the access request is greater than an estimated latency period, latency handler 130 may stall processor 120 based on the time difference between the actual latency period and the estimated latency period.

Tag ID generator 150 generates a tag ID to identify an access request regarding main memory 200. Specifically, processor 120 transmits various types of access requests regarding main memory 200, and the tag ID generator 150 may assign a generated tag ID to each access request in order to identify such an access request.

If the actual latency period of an access request is less than an estimated latency period, latency handler 130 may buffer a response corresponding to the access request for a predetermined time, and if the actual latency period of the access request is greater than the estimated latency period, latency handler 130 may stall processor 120 for a predetermined time.

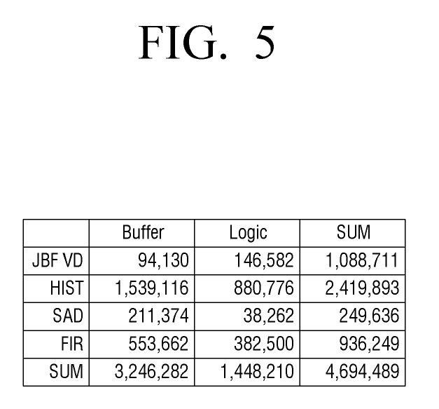

FIG. 5 is a view illustrating a detailed area ratio of a buffer according to an exemplary embodiment.

Referring to FIG. 5, in the case of a feature map, which requires processing of large amount of one-off data, a unit for processing three FIR filters are simultaneously needed to process a high definition image of 4K, and two histogram processors, one sum of absolute difference (SAD), and one joint bilateral filter (JBF) are needed. In this case, as illustrated in the table of FIG. 5, a buffer memory has the scale of more than 3M G/C in order to process the feature map.

According to an exemplary embodiment, a buffer memory can be removed by using a main memory instead of the buffer memory and thus, the size of memory can be reduced, thereby saving production cost.

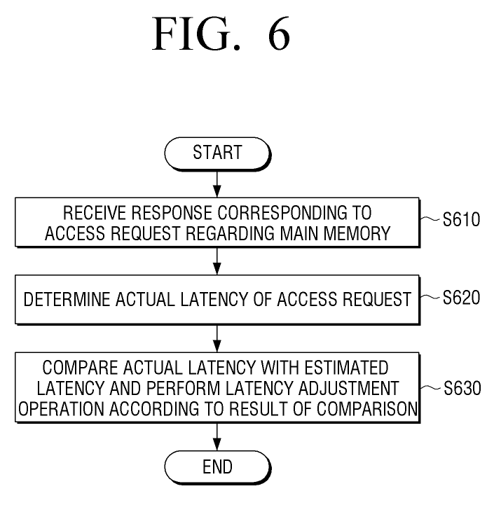

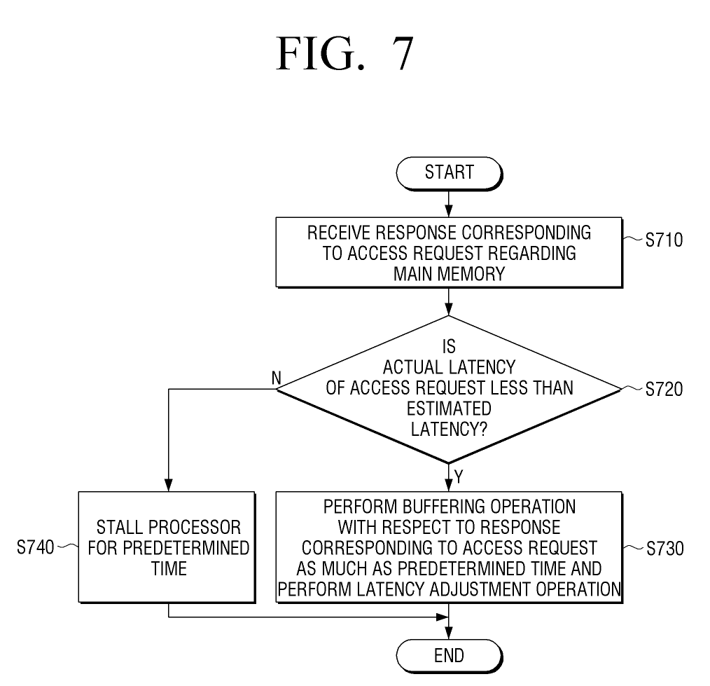

FIGS. 6 and 7 are flowcharts illustrating a control method of a memory controller according to an exemplary embodiment.

According to the control method of a memory controller illustrated in FIG. 6, initially, a response corresponding to an access request regarding a main memory is received (S610).

Subsequently, the actual latency of the access request is determined (S620). In this case, the actual latency of the access request may be determined based on the time duration of receiving the response corresponding to the access request.

The actual latency of the access request is compared with estimated latency of the access request, and a latency adjustment operation corresponding to a result of the comparison is performed (S630).

According to the control method of a memory controller illustrated in FIG. 7, initially a response corresponding to an access request regarding a main memory is received (S710).

Subsequently, determine whether the actual latency of the access request is less than the estimated latency (S720).

If the actual latency of the access request is less than the estimated latency in step S720 (5720:Y), a buffering operation is performed with respect to a response corresponding to the access request as much as a predetermined time, and a latency adjustment operation corresponding to the response is performed (S730).

On the other hand, if the actual latency of the access request is greater than the estimated latency in step S620 (S620:N), the processor may be stalled for a predetermined time and then, a latency adjustment operation corresponding to the response may be performed (S740).

In step S720, a tag ID for identifying an access request may be assigned to the access request, and actual latency period of the access request may be determined based on the tag ID of the access request and the time duration of receiving a response corresponding to the access request.

As described above, according to the various exemplary embodiments, the latency period of a main memory access request may be adjusted to a fixed latency period and thus, the main memory can be used more effectively.

Meanwhile, the methods according to the above-described various exemplary embodiments may be implemented simply by upgrading software regarding the existing memory controller.

In addition, a non-transitory computer readable medium storing a program to perform the control method according to an exemplary embodiment sequentially may be provided.

For example, a non-transitory computer readable medium storing a program for performing the steps of receiving a response corresponding to an access request regarding a main memory, determining the actual latency period of the request based on the time duration of receiving the response, comparing the actual latency period with estimated latency period, and performing a latency adjustment operation corresponding to a result of the comparison may be provided.

The non-transitory recordable medium refers to a medium which may store data semi-permanently rather than storing data for a short time, such as register, cache, memory, etc. and is readable by an apparatus. Specifically, the above-described various applications and programs may be stored and provided in a non-transitory recordable medium such as CD, DVD, hard disk, Blu-ray disk, USB, memory card, ROM, etc.

The foregoing exemplary embodiments and advantages are merely exemplary and are not to be construed as limiting the present disclosure. The present teaching can be readily applied to other types of apparatuses. Also, the description of the exemplary embodiments of the present disclosure is intended to be illustrative, and not to limit the scope of the claims, and many alternatives, modifications, and variations will be apparent to those skilled in the art.

What is claimed is:

1. A memory controller, comprising:
a communication module configured to perform communication with a main memory; and
a processor configured to, based on time duration of receiving a response corresponding to a request to access the main memory, determine an actual latency period of the access request, compare the actual latency period with an estimated latency period, and perform a latency adjustment operation to adjust the actual latency period to correspond to the estimated latency based on a result of the comparison.

2. The memory controller of claim 1, wherein the processor is further configured to, perform the latency adjustment operation in response to the actual latency period of the access request being less than the estimated latency period, buffer a response to the access request based on a time difference between the actual latency period and the estimated latency period, and
wherein the processor is further configured to provide the response to an application making the access request to the main memory.

3. The memory controller of claim 1, wherein the processor is further configured to, perform the latency adjustment operation in response to the actual latency period of the access request being greater than the estimated latency period, and stall the processor as much as a time difference between the actual latency period and the estimated latency period.

4. The memory controller of claim 1, wherein the processor is further configured to, assign a tag ID to the access request, and determine the actual latency period of the access request based on the tag ID and the time duration.

5. The memory controller of claim 1, wherein the processor further comprises:
a tag ID generator configured to assign a tag ID to the access request; and
a latency handler configured to perform the latency adjustment operation.

6. The memory controller of claim 1, wherein the access request is a request to access one-off data stored in the main memory.

7. The memory controller as claimed in claim 1, wherein the main memory is a dynamic random access memory (DRAM).

8. An electronic apparatus, comprising:
a main memory; and
a memory controller configured to transmit an access request to the main memory, determine an actual latency period of the access request based on a time duration of receiving a response corresponding to the access request, compare the actual latency period with an estimated latency period, and perform an latency adjustment operation to adjust the actual latency period to correspond to the estimated latency period based on a result of the comparison.

9. A method of a memory controller controlling latency of requests to access main memory, the method comprising:
receiving a response corresponding to a request to access a main memory;
determining an actual latency period of the access request based on a time duration of receiving the response;
comparing the actual latency period with an estimated latency period; and
performing a latency adjustment operation to adjust the actual latency period to correspond to the estimated latency period based on a result of the comparison.

10. The method of claim 9, wherein the performing comprises performing the latency adjustment operation in response to the actual latency period of the access request being less than the estimated latency period, buffering the response based on a time difference between the actual latency period and the estimated latency period, and providing the response to an application requesting access to the main memory.

11. The method of claim 9, wherein the performing comprises performing the latency adjustment operation in response to the actual latency period of the access request being greater than the estimated latency period, stalling a processor based on a time difference between the actual latency period and an estimated latency period, and providing the response to an application requesting access to the main memory.

12. The method of claim 9 further comprising, assigning a tag ID to the access request, and determining the actual latency period of the request based on the tag ID and the time duration.

13. The method of claim 9, wherein the access request is a request to access one-off data stored in the main memory.

14. The method as claimed in claim 9, wherein the main memory is a dynamic random access memory (DRAM).
